(19) United States
(12) Patent Application Publication
(10) Pub. No.: US 2015/0206765 A1
(43) Pub. Date: Jul. 23, 2015

(54) Mechanical Compression-Based Method for the Reduction of Defects in Semiconductors

(71) Applicant: Sandia Corporation, Albuquerque, NM (US)

(72) Inventors: Qiming Li, Shanghai (CN); Hongyou Fan, Albuquerque, NM (US)

(21) Appl. No.: 14/595,005

(22) Filed: Jan. 12, 2015

Related U.S. Application Data
(60) Provisional application No. 61/928,517, filed on Jan. 17, 2014.

(51) Int. Cl. H01L 21/322; H01L 21/46

(52) U.S. Cl. CPC H01L 21/322; H01L 21/46

(57) ABSTRACT

A high pressure-directed engineering method enables reduced defect semiconductor materials that are unattainable by other chemical and physical methods. Experimental results show that hydraulic pressures as low as 0.5 GPa can eliminate stacking faults and significantly reduce point defects, leading to improved materials quality in semiconductors, such as GaN.

### CROSS-REFERENCE TO RELATED APPLICATION

This application claims the benefit of U.S. Provisional Application No. 61/928,517, filed Jan. 17, 2014, which is incorporated herein by reference.

### STATEMENT OF GOVERNMENT INTEREST

This invention was made with Government support under contract no. DE-AC04-94AL85000 awarded by the U.S. Department of Energy to Sandia Corporation. The Government has certain rights in the invention.

### FIELD OF THE INVENTION

The present invention relates to defects in semiconductors and, in particular, to a mechanical compression-based method for the reduction of defects in semiconductors.

### BACKGROUND OF THE INVENTION

High quality semiconductor materials with low defect densities, such as III-nitride semiconductors, lead to more efficient, reliable UV to visible light-emitting diodes (LEDs), lasers, radiation detector, and RF devices with obvious impact in electronics, communications and surveillance. However, intrinsic defects such as stacking faults, threading dislocations, and point defects can seriously deteriorate semiconductor device reliability, efficiencies, and lifetimes. Therefore, strategies for the reduction of defects are of immense technological importance. Current efforts primarily focus on technologies during growth/deposition processes, such as lateral epitaxial overgrowth techniques. However, the added cost, time, and complexity of these processes are undesirable.

Therefore, a need remains for a post-growth method of reducing defects in semiconductors.

### SUMMARY OF THE INVENTION

The present invention is directed to a method for reducing defects in semiconductor material by mechanical compression comprising providing a semiconductor material having defects; and applying sufficient pressure to the semiconductor material to compress and reduce the defects in the semiconductor material. The sufficient pressure can typically be greater than 0.5 GPa. For example, the semiconductor material can be in the form of a thin film, powder, or an array of micro- or nano-structures (e.g., nanowires, nanocolumns, nanopillars, nanorods, or micro-variations thereof). The semiconductor material can comprise a II-VI semiconductor or a III-V semiconductor, such as a III-nitride semiconductor including gallium nitride, indium nitride, aluminum nitride, or alloys thereof. For example, the pressure can be applied with a diamond anvil cell, a piston-cylinder device, multi-anvil cell, imprinting, or embossing machine.

The method mimics embossing and imprinting manufacturing processes and opens an exciting new avenue for large-scale fabrication and processes for reduction of defects in a wide variety of semiconductor materials, as well as other materials generally where defect removal is desired.

### BRIEF DESCRIPTION OF THE DRAWINGS

The detailed description will refer to the following drawings, wherein like elements are referred to by like numbers.

FIG. 1 is a schematic illustration of a mechanical compression-based method for reduction of defects in semiconductor materials.

FIG. 2 is a schematic illustration of stacking order in a GaN crystal.

FIG. 3 is a graph of wide angle x-ray patterns of GaN nanowires during compression up to ˜15 GPa and pressure releasing.

FIG. 4(a)-FIG. 4(c) are graphs of the d-spacing of different peaks during the compression and release process: FIG. 4(a) d₁₀₀, FIG. 4(b) d₀₀₂, and FIG. 4(c) d₁₀₁.

FIG. 5 is a graph of wide angle x-ray patterns of GaN nanowires during compression and pressure releasing.

FIG. 6 is a graph of zoomed stack fault peaks and normalized wide angle x-ray scattering patterns.

FIG. 7(a) is a graph of the full width at half maximum (FWHM) of each XRD peaks of GaN nanowires in FIG. 5 after release from various pressures. FIG. 7(b) is a graph of the peak intensity of the GaN nanowires in the XRD patterns at the ambient pressure after release from various pressures.

FIG. 8 shows the photoluminescence of GaN nanowires before and after high-pressure compression.

### DETAILED DESCRIPTION OF THE INVENTION

The discovery and understanding of high-pressure engineering processes has generated new scientific research and advanced scientific knowledge in defect reduction and the formation of new metal, semiconducting, and magnetic nanostructures that cannot be fabricated using conventional methods. Given that the low-pressure devices are readily and commercially available, the overall complexity and cost for defect reduction of epitaxial semiconductors can be drastically reduced with increased throughput using mechanical-compression based methods. The mechanical-compression method is a significant departure from current defect mitigation techniques, which rely on complex defect blocking masks, high temperature annealing, or re-crystallization that may be incompatible with the material or device. See S. D. Hersee et al., IEEE J. Quantum Electron. 38, 1017 (2002); Lei Li et al., Appl. Phys. Express 5 (2012); and J. C. Zolper et al., Appl. Phys. Lett. 68, 200 (1996). As an example of the present invention, below is described a mechanical compression-based method for the reduction of defects in GaN nanowire materials.

### Gallium Nitride Nanowires

Growth of GaN-based nanowire LEDs by bottom-up methods, including hydride vapor phase epitaxy and molecular beam epitaxy (MBE), has been demonstrated. See H.-M. Kim et al., Nano Lett. 4, 1059 (2004); H. W. Lin et al., Appl. Phys. Lett. 97, 073101 (2010) and H. P. T. Nguyen et al., Nano Lett. 11, 1919 (2011). However, metal catalyzed-grown GaN-based nanowires require narrow growth conditions which involves lower than optimal growth temperatures. See G. T. Wang et al., Nanotechnology 17, 5773 (2006). These growth conditions may introduce higher impurities and point defect densities than the conditions used for creating commercial-quality planar LEDs and provide less flexibility for adjusting growth parameters to optimize doping concentrations and other desired material properties. See A. A. Talin et al., Appl. Phys. Lett. 92, 093105 (2008); and P. C. Upadhya et al., Semiconductor Science and Technology 25, 024017 (2010).

As an example, GaN nanowires were grown on a sapphire substrate in a metal organic chemical vapor deposition (MOCVD) system. Before the growth, a 0.8 nm thick nickel layer was first coated on an r-plane sapphire substrate by electron beam evaporation. The nickel layer breaks into nickel dots through a dewetting process when the sapphire wafers are heated to the desired growth temperature in the MOCVD. The precursors were then introduced into the MOCVD chamber and the nickel dots catalyzed the nucleation and elongation of the GaN nanowires. The growth rate of these nanowires is typically 1 micron per minute. While the length of the nanowire grows, the diameter of the nanowire is also enlarged, but at a much slower rate. After a few minutes growth, a layer of a few microns long GaN nanowires was achieved. The GaN nanowires were single crystalline with growth direction vertical to a-plane. However, defects, such as stacking faults and impurities, exist in the as-grown nanowires. This nanowire layer was scraped off the sapphire substrates prior to mechanical compression.

### Mechanical Compression

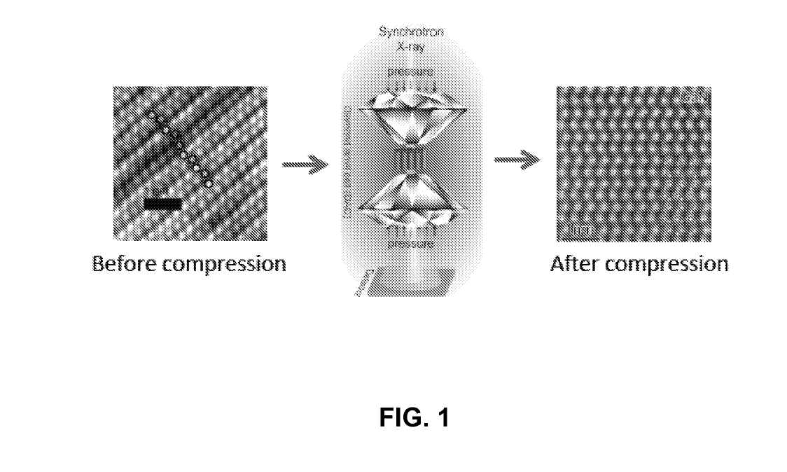

As shown in FIG. 1, a diamond anvil cell (DAC) can be used to mechanically compress the GaN nanowires. A DAC consists of two opposing diamonds with a sample compressed between the culets. Pressure can be monitored using a reference material, such as ruby fluorescence, whose behavior under pressure is known. The uniaxial pressure supplied by the DAC can be transformed into uniform hydrostatic pressure using a pressure transmitting medium, such as a liquid or polymer, in which the semiconductor material can be embedded. For example, liquid silicone oil or polystyrene can be used as the pressure-transmitting medium. The pressure-transmitting medium is enclosed by a gasket and the two diamond anvils. Transparency of the DAC allows in-situ optical characterization and monitoring of the structural evolution of the nanowire samples using synchrotron x-ray scattering. In particular, in-situ synchrotron X-ray diffraction (XRD) measurements coupled with photoluminescence enables monitoring of defect reduction upon mechanical compression. Other low- and moderate-pressure devices can also be used to mechanically compress the semiconductor material, such as piston-cylinder devices, multi-anvil cells, or embossing machines.

### XRD Characterizations of Defects and Reduction

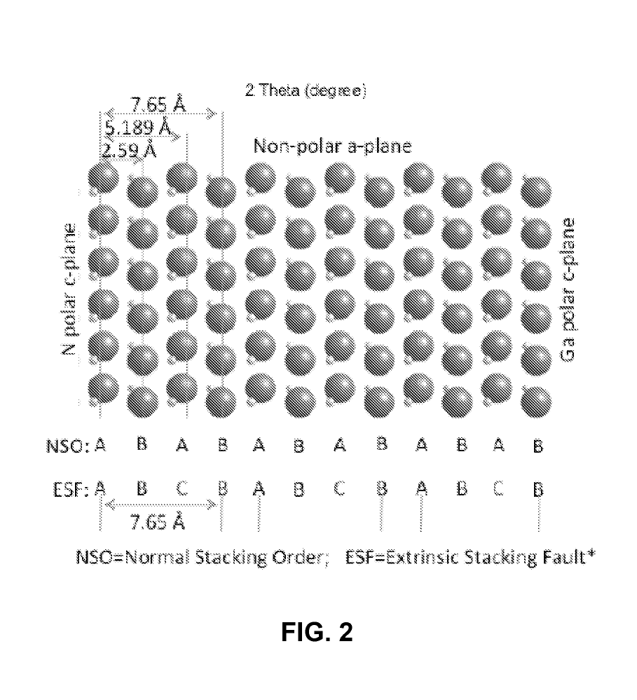

Defects are particularly common in III-nitride semiconductors, due to the lack of native substrates. GaN epitaxial layers have been primarily grown on substrates such as sapphire, SiC, GaAs, and Si. FIG. 2 is a schematic illustration of stacking order in a GaN crystal. The major structural defects in wurtzite GaN are extended defects, such as those related to stacking mismatch and dislocations. Stacking faults are irregularities in the ordering of layers of atoms that do not necessitate the breaking of bonds, such as transforming from the hexagonal stacking order ABAB . . . to the ABC . . . stacking order that characterizes cubic (zinc blende) systems. The wurtzite structure has a hexagonal unit cell, and thus two lattice parameters, a in the (0001) basal plane and c in the perpendicular direction. Therefore, c depicts the unit cell height (i.e., 5.189 A). The wurtzite structure consists of two interpenetrating hexagonal close-packed (hcp) sublattices, each with one type of atom, offset along the c-axis by ⅝ of the cell height (i.e., 5c/8). The GaN wurtzite structure consists of alternating biatomic close-packed (0001) planes of Ga and N pairs, thus the normal stacking order of the (0001) planes is ABAB . . . in the [0001] c-direction. The energies associated with stacking faults are very small, so they are easy to form and, in principle, easy to reduce or eliminate. For example, basal plane stacking faults easily occur during epitaxial growth of GaN when atoms can occupy either the B or C positions above an A layer. Because GaN does not share the same atomic stacking order as the substrate, the crystal direction [0001] of GaN film, the direction of the long bond along the c-axis from Ga to N atoms, can be either parallel or antiparallel to the growth direction. The epilayer in the former case is referred to as Ga-polarity, whereas it is referred to as N-polarity in the latter case. GaN layers grown by MBE can be either N- or Ga-polarity. Therefore, instead of maintaining the AB stacking along the c-direction throughout the crystal, stacking orders such as extrinsic stacking faults ABABCABAB . . . can occur. The d-spacing of the extrinsic stacking fault in the basal plane of GaN is 7.65 angstroms. See A. F. Wright et al., J. Appl. Phys. 82, 5259 (1997).

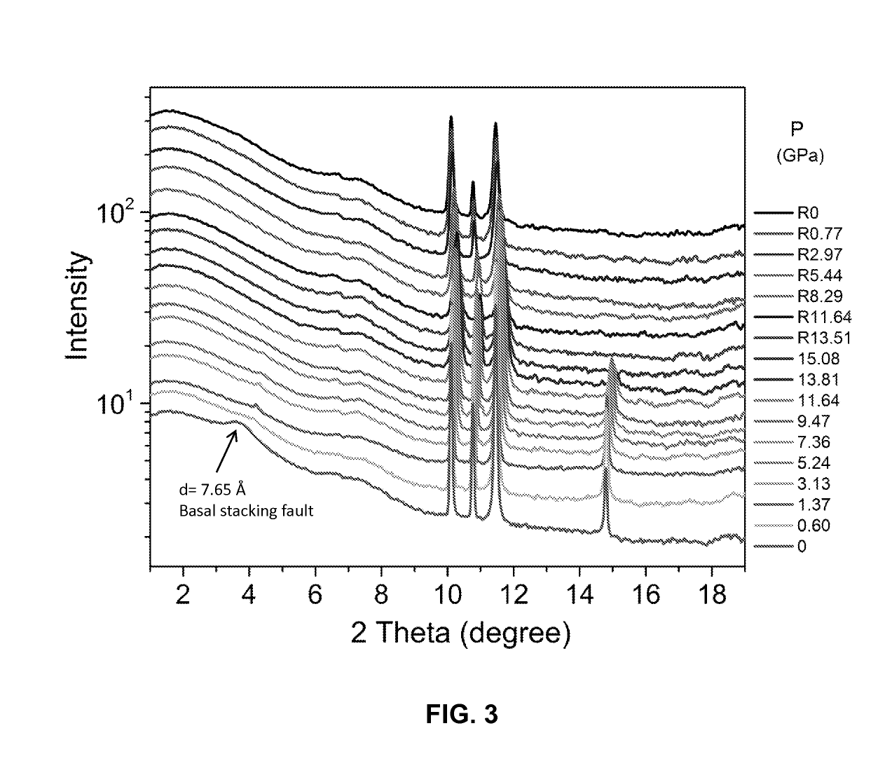

To monitor the structural evolution of stacking faults, in-situ high-pressure synchrotron X-ray analysis was performed while the GaN nanowire samples were pressurized in a diamond anvil cell. FIG. 3 is a graph of wide angle x-ray patterns of GaN nanowires during compression up to about 15 GPa and upon pressure release from 15 GPa back down to 0 GPa. Prior to compression, the GaN nanowire crystal can be indexed as hexagonal phase, P63mc, with a unit cell size to be 3.186 Å (a)×3.186 Å (b)×5.176 Å (c) and d₁₀₀=2.76 Å, d₀₀₂=2.59 Å, d₁₀₁=2.43 Å. A basal stacking fault (d=7.65 Å) appeared in the uncompressed sample at 0 GPa, but disappeared when the sample was compressed to 0.60 GPa, indicating the defect was significantly removed at a low pressure. All the XRD peaks shifted to larger 2 theta up to the highest pressure at 15.08 GPa, indicating shrinkage of the unit cell upon compression. When the pressure was released back down to the ambient pressure (R0), all of these peaks reverted back to their original positions, suggesting the overall crystal structure returns back to the original hexagonal phase. However, as the pressure was released, the peak at d=7.65 Å did not recover, indicating an irreversible stacking fault removal.

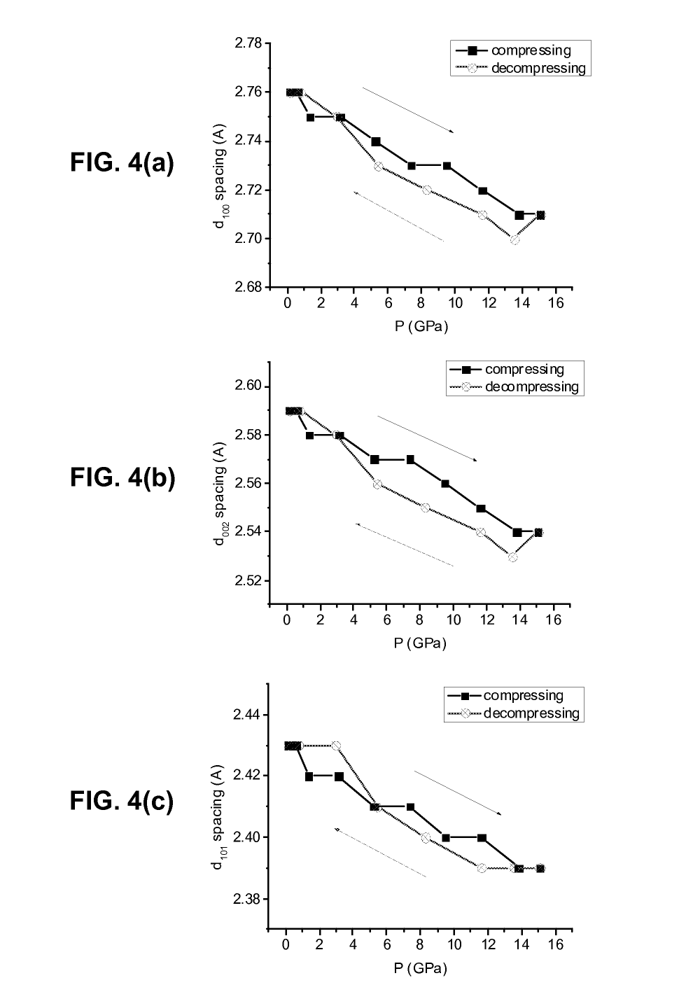

FIGS. 4(a)-(c) are graphs of the d-spacings for the d₁₀₀, d₀₀₂, and d₁₀₁ peaks during the compression and release process. As shown in this figure, when the pressure increases, the d-spacing decreases for all crystal orientations. When the pressure is released from about 15 GPa, all the peaks return essentially back to the original values at ambient condition, which indicates the crystal structure recovers upon decompression.

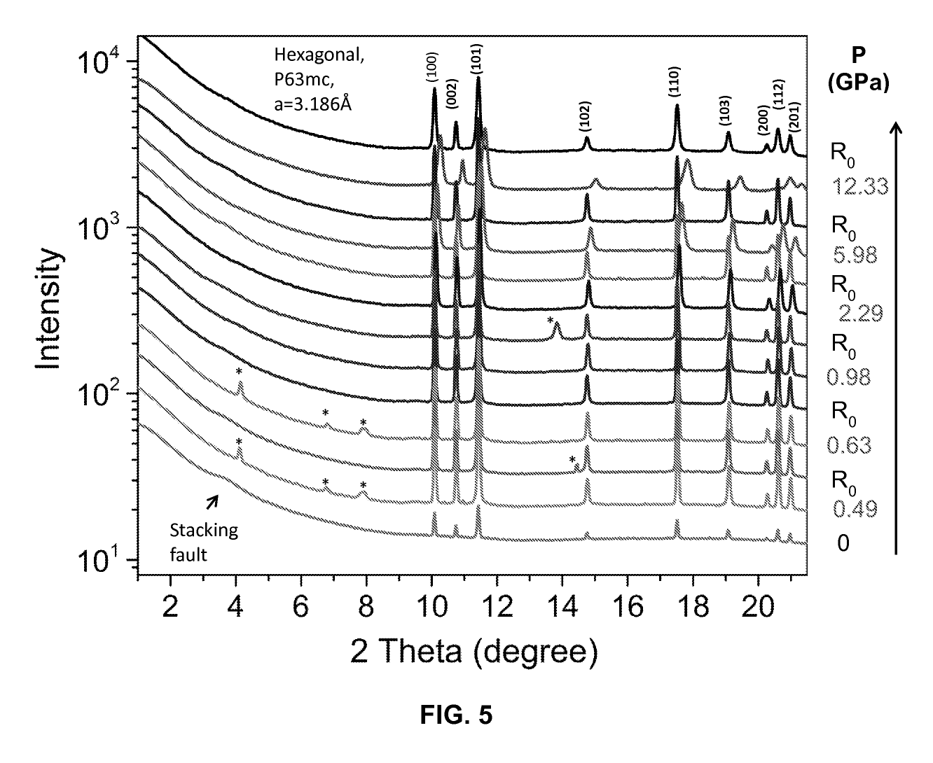

FIG. 5 is a graph of wide angle x-ray patterns of GaN nanowires during repeated compression and release to increasingly higher pressures (the asterisk * indicates peaks from Fe and other impurities). Specifically, the pressure was increased from the ambient condition to a certain higher pressure, then the pressure was released back to the ambient condition (R₀). The cycling was repeated up to a maximum pressure of 12.33 GPa. From this figure, it is apparent that the stacking fault (d=7.65 Å) was dramatically reduced/removed even at the lowest pressure applied of ˜0.49 GPa.

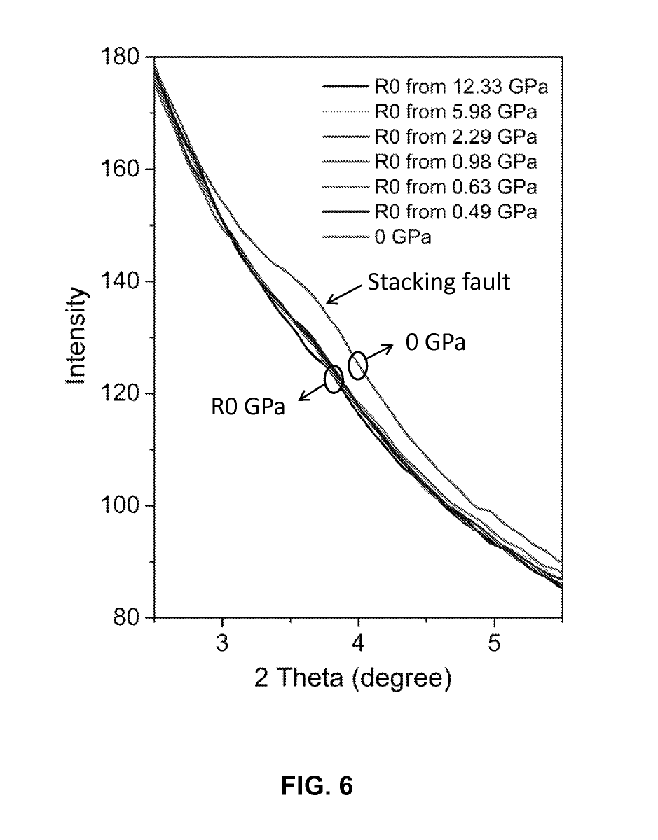

FIG. 6 is a graph of the zoomed XRD patterns shown in FIG. 5 in the vicinity of the stacking fault XRD peak. The disappearance of stacking fault peak at d=7.65 Å demonstrates that the defect was significantly reduced and/or removed after applying of any pressure higher than about 0.5 GPa.

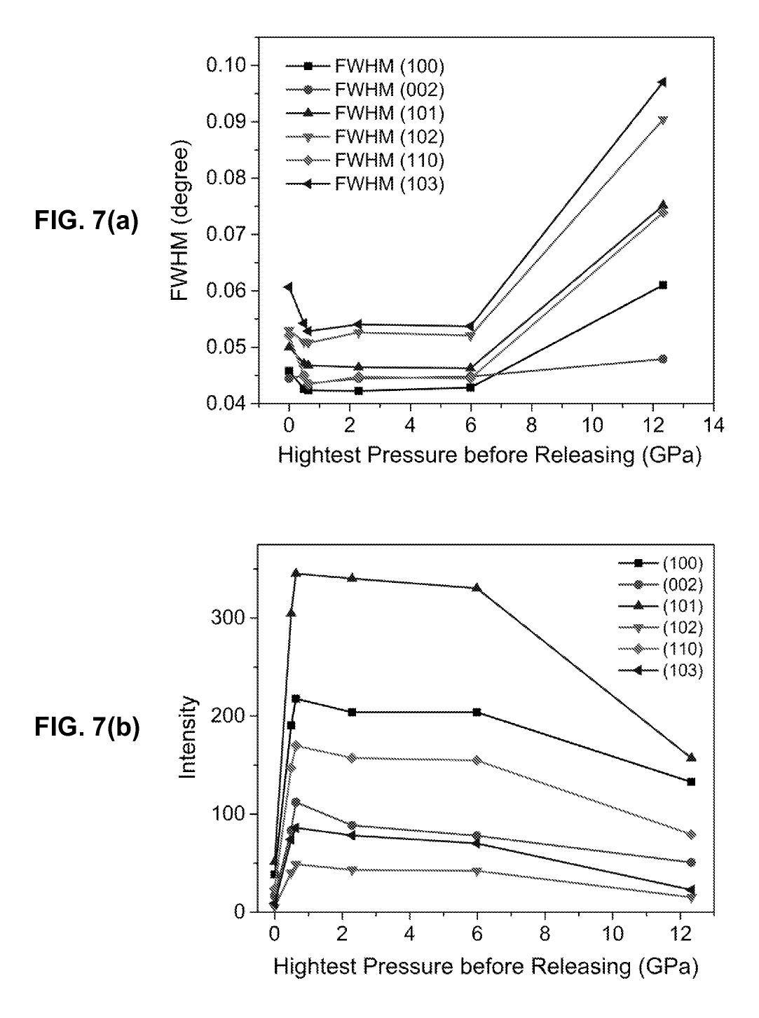

FIG. 7(a) is a graph of the full width at half maximum (FWHM) of each of the XRD crystal peaks in FIG. 5 after the pressure was released from the pressure indicated. When the applied pressures was below about 6 GPa, all of the peaks became a little bit narrower than the original uncompressed sample, indicating that the crystal domain size increased and the crystal became more perfect than the original sample. However, after the pressure increased to 12.33 GPa, all of the peaks broaden significantly, indicating the crystal domain was broken to smaller sizes upon application of pressures between about 6 and 12 GPa. This suggests that 0.5-6 GPa is the best range of pressure that can effectively remove defects but not to damage the crystal structure. FIG. 7(b) is a graph of the peak intensity of the XRD peaks at ambient pressure after release from the pressure indicated. From this peak intensity plot, it is clearly seen that after applying pressure the peak intensity increases dramatically up to the point where ˜6 GPa was applied. This suggests that stress can enable a more perfect crystal structure than the original specimen. The threshold pressure 6 GPa is consistent with that observed in FIG. 7(a).

### Optical Characterizations of GaN Nanowires

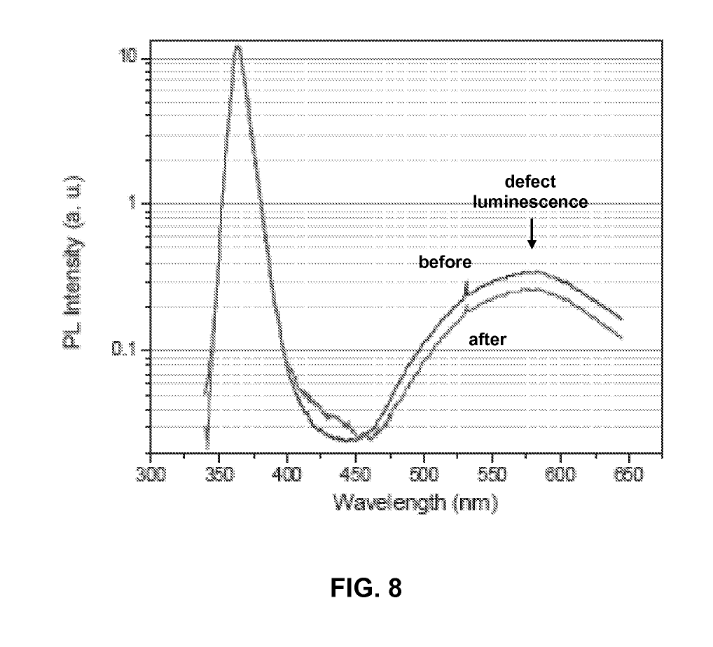

A photoluminescence study on the GaN nanowires samples was performed before and after the compression experiments. In FIG. 8, the photoluminescence spectra before and after the pressure experiments are normalized by the peak intensity for GaN band edge emission at 367 nm so that the yellow luminescence centered at 550 nm can be compared. The yellow luminescence is well known to be caused by point defects. See Q. Li and G. Wang, Nano Letters 10(5), 1554 (2010). After the pressure experiments, the GaN nanowire sample show a ˜60% reduction in defect-related yellow luminescence and concomitant 20% enhancement in ˜365 nm band edge emission. These findings suggest that high-pressure compression activates multiple atomic processes involving defect motion or annihilation processes that produce observable and beneficial changes in the material optical properties.

The present invention has been described as a mechanical compression-based method for the reduction of defects in semiconductors. It will be understood that the above description is merely illustrative of the applications of the principles of the present invention, the scope of which is to be determined by the claims viewed in light of the specification. Other variants and modifications of the invention will be apparent to those of skill in the art.

We claim:

1. A method for reducing defects in semiconductor material by mechanical compression, comprising:
providing a semiconductor material having defects; and
applying sufficient pressure to the semiconductor material to compress and reduce the defects in the semiconductor material.

2. The method of claim 1, wherein the semiconductor material comprises a II-VI semiconductor material or a III-V semiconductor material.

3. The method of claim 2, wherein the III-V semiconductor material comprises a III-nitride semiconductor material.

4. The method of claim 3, wherein the III-nitride semiconductor material comprises gallium nitride, indium nitride, aluminum nitride, or alloys thereof.

5. The method of claim 3, wherein the III-nitride semiconductor material comprises a GaN nanowire material.

6. The method of claim 1, wherein the semiconducting material comprises a thin film, powder, or microstructure, or nanostructure.

7. The method of claim 1, wherein the sufficient pressure is greater than 0.5 GPa.

8. The method of claim 7, wherein the sufficient pressure is less than 6 GPa.

9. The method of claim 1, wherein the step of applying sufficient pressure comprises embedding the semiconductor material in a pressure-transmitting medium comprising a liquid or polymer.

10. The method of claim 1, wherein the pressure is applied with a diamond anvil cell.

11. The method of claim 1, wherein the pressure is applied with a piston-cylinder device, multi-anvil cell, imprinting, or embossing machine.

12. The method of claim 1, further comprising releasing the pressure to ambient after reducing the defects in the semiconductor material.

13. The method of claim 1, wherein the step of applying sufficient pressure induces at least partial removal of the defects.

14. The method of claim 1, wherein the step of applying sufficient pressure induces at least partial decrease of a defect related-fluorescence of the semiconducting material.

15. The method of claim 1, wherein the step of applying sufficient pressure induces at least partial disappearance of defects related phase structure.

16. The method of claim 1, wherein the defects comprise a stacking fault defect.

17. The method of claim 1, wherein the defects comprise a point defect.
